(19) United States
(12) Patent Application Publication
(10) Pub. No.: US 2009/0150750 A1
(43) Pub. Date: Jun. 11, 2009

(54) METHOD AND APPARATUS FOR HARQ ENCODING WITH LOW MEMORY REQUIREMENT

(75) Inventors: Jingyuan Liu, Morris Plains, NJ (US); Bhupinder S. Parhar, Belle Mead, NJ (US); Vikram R. Anreddy, Bridgewater, NJ (US)

Correspondence Address: QUALCOMM INCORPORATED, 5775 MOREHOUSE DR., SAN DIEGO, CA, 92121, US

(73) Assignee: QUALCOMM INCORPORATED, San Diego, CA (US)

(21) Appl. No.: 12/328,704

(22) Filed: Dec. 4, 2008

Related U.S. Application Data
(60) Provisional application No. 60/992,433, filed on Dec. 5, 2007.

(51) Int. Cl. H03M 13/09

(52) U.S. Cl. 714/758; 714/E11.04

(57) ABSTRACT

An apparatus and method for hybrid automatic repeat request (HARQ) encoding comprising re-encoding a subpacket from a plurality of subpackets to obtain a codeword; maintaining a set of state variables for each of the plurality of subpackets; initializing the set of state variables at HARQ transmit start; updating the set of state variables at HARQ transmit end; and using the set of updated state variables to determine a portion of the codeword to be transmitted.

### CLAIM OF PRIORITY UNDER 35 U.S.C. § 119

The present application for patent claims priority to Provisional Application No. 60/992,433, entitled HARQ Encoding Scheme With Low Memory Requirement filed on Dec. 5, 2007, and assigned to the assignee hereof and hereby expressly incorporated by reference herein.

### FIELD

This disclosure relates generally to apparatus and methods for encoding. More particularly, the disclosure relates to hybrid automatic repeat request (HARQ) encoding scheme with low memory requirement.

### BACKGROUND

Wireless communication systems are widely deployed to provide various types of communication content such as voice, data, and so on. These systems may be multiple-access systems capable of supporting communication with multiple users by sharing the available system resources (e.g., bandwidth and transmit power). Examples of such multiple-access systems include code division multiple access (CDMA) systems, time division multiple access (TDMA) systems, frequency division multiple access (FDMA) systems, 3GPP LTE systems, and orthogonal frequency division multiple access (OFDMA) systems.

Generally, a wireless multiple-access communication system can simultaneously support communication for multiple wireless terminals. Each terminal communicates with one or more base stations via transmissions on the forward and reverse links. The forward link (or downlink) refers to the communication link from the base stations to the terminals (e.g., a mobile station), and the reverse link (or uplink) refers to the communication link from the terminals to the base stations. This communication link may be established via a single input-single output, multiple input-single output or a multiple-input-multiple-output (MIMO) system.

A MIMO system employs multiple (N_{T}) transmit antennas and multiple (N_{R}) receive antennas for data transmission. A MIMO channel formed by the N_{T} transmit and N_{R} receive antennas may be decomposed into N_{S} independent channels, which are also referred to as spatial channels, where N_{S}≦min{N_{T}, N_{R}}. Each of the N_{S} independent channels corresponds to a dimension. The MIMO system can provide improved performance (e.g., higher throughput and/or greater reliability) if the additional dimensionalities created by the multiple transmit and receive antennas are utilized. For example, a MIMO system can support time division duplex (TDD) and frequency division duplex (FDD) systems. In a TDD system, the forward and reverse link transmissions are on the same frequency region so that the reciprocity principle allows the estimation of the forward link channel from the reverse link channel. This enables the access point to extract transmit beamforming gain on the forward link when multiple antennas are available at the access point.

Wireless communication systems are subject to various channel perturbations and noise disturbances which are introduced somewhere in the wireless link. These imperfections result in errors in the data processed by a receiver. In general, there are two broad categories of error control applicable to wireless communication systems, error detection and error correction. Error detection techniques, such as automatic repeat request (ARQ), typically add a few redundant bits to a transmit data frame for the purpose of error detection. If an error is detected, the receiver typically sends back an error detection message to the transmitter to request a retransmission of the same transmit data frame. In contrast, error correction techniques, such as forward error correction (FEC), typically add more redundant bits in a structured manner to a transmit data frame for the purpose of error correction. Error correction allows the receiver to both detect and correct received errors, without feedback and retransmission. Depending on the channel error characteristics and throughput versus latency requirements on the system, error detection or error correction might be preferred.

### SUMMARY

Disclosed is an apparatus and method for HARQ encoding scheme with low memory requirement. According to one aspect, a method for hybrid automatic repeat request (HARQ) encoding comprising re-encoding a subpacket from a plurality of subpackets to obtain a codeword; maintaining a set of state variables for each of the plurality of subpackets; initializing the set of state variables at HARQ transmit start; updating the set of state variables at HARQ transmit end; and using the set of updated state variables to determine a portion of the codeword to be transmitted.

According to another aspect, a transmit data processor for hybrid automatic repeat request (HARQ) encoding comprising a channel encoder module configured to: a) re-encode a subpacket from a plurality of subpackets to obtain a codeword; b) maintain a set of state variables for each of the plurality of subpackets; c) initialize the set of state variables at HARQ transmit start; and d) update the set of state variables at HARQ transmit end; and a multiplexer module configured to use the set of updated state variables to determine a portion of the codeword to be transmitted.

According to another aspect, an apparatus for hybrid automatic repeat request (HARQ) encoding comprising means for re-encoding a subpacket from a plurality of subpackets to obtain a codeword; means for maintaining a set of state variables for each of the plurality of subpackets; means for initializing the set of state variables at HARQ transmit start; means for updating the set of state variables at HARQ transmit end; and means for using the set of updated state variables to determine a portion of the codeword to be transmitted.

According to another aspect, a computer-readable medium including program code stored thereon, comprising program code for re-encoding a subpacket from a plurality of subpackets to obtain a codeword; program code for maintaining a set of state variables for each of the plurality of subpackets; program code for initializing the set of state variables at HARQ transmit start; program code for updating the set of state variables at HARQ transmit end; and program code for using the set of updated state variables to determine a portion of the codeword to be transmitted.

Advantages of the present disclosure include reducing chip memory without increasing peak processor speed budget. In one example, the memory saving is approximately five times that of conventional approach.

It is understood that other aspects will become readily apparent to those skilled in the art from the following detailed description, wherein it is shown and described various aspects by way of illustration. The drawings and detailed description are to be regarded as illustrative in nature and not as restrictive.

### BRIEF DESCRIPTION OF THE DRAWINGS

FIG. 1 is a block diagram illustrating an example of a multiple access wireless communication system.

FIG. 2 is a block diagram illustrating an example of a wireless MIMO communication system.

FIG. 3 is a block diagram illustrating an example of a transmit data processor for HARQ encoding.

FIG. 4 is a block diagram illustrating an example of the front-end of the transmit data processor of FIG. 3.

FIGS. 5a and 5b illustrate examples of MAC packet descriptor for immediate and indirect cases, respectively.

FIG. 6 is a block diagram illustrating a more detailed example of a transmit data processor for HARQ encoding.

FIG. 7 illustrates an example of a hybrid ARQ operation.

FIG. 8 illustrates an example of an assignment history mechanization.

FIG. 9 illustrates an example multiplexer assignment description.

FIG. 10 illustrates an example timeline for the HARQ transmissions.

FIG. 11 illustrates an example timeline for HARQ transmissions with extended frames.

FIG. 12 illustrates an example flow diagram for hybrid automatic repeat request (HARQ) encoding with low memory requirement.

FIG. 13 illustrates an example of a device comprising a processor in communication with a memory for hybrid automatic repeat request (HARQ) encoding with low memory requirement.

FIG. 14 illustrates an example of a device suitable for hybrid automatic repeat request (HARQ) encoding with low memory requirement.

### DETAILED DESCRIPTION

The detailed description set forth below in connection with the appended drawings is intended as a description of various aspects of the present disclosure and is not intended to represent the only aspects in which the present disclosure may be practiced. Each aspect described in this disclosure is provided merely as an example or illustration of the present disclosure, and should not necessarily be construed as preferred or advantageous over other aspects. The detailed description includes specific details for the purpose of providing a thorough understanding of the present disclosure. However, it will be apparent to those skilled in the art that the present disclosure may be practiced without these specific details. In some instances, well-known structures and devices are shown in block diagram form in order to avoid obscuring the concepts of the present disclosure. Acronyms and other descriptive terminology may be used merely for convenience and clarity and are not intended to limit the scope of the disclosure.

While for purposes of simplicity of explanation, the methodologies are shown and described as a series of acts, it is to be understood and appreciated that the methodologies are not limited by the order of acts, as some acts may, in accordance with one or more aspects, occur in different orders and/or concurrently with other acts from that shown and described herein. For example, those skilled in the art will understand and appreciate that a methodology could alternatively be represented as a series of interrelated states or events, such as in a state diagram. Moreover, not all illustrated acts may be required to implement a methodology in accordance with one or more aspects.

The techniques described herein may be used for various wireless communication systems such as Code Division Multiple Access (CDMA) systems, Time Division Multiple Access (TDMA) systems, Frequency Division Multiple Access (FDMA) systems, Orthogonal FDMA (OFDMA) systems, Single-Carrier FDMA (SC-FDMA) systems, etc. The terms “systems” and “networks” are often used interchangeably. A CDMA system may implement a radio technology such as Universal Terrestrial Radio Access (UTRA), cdma2000, etc. UTRA includes Wideband-CDMA (W-CDMA) and Low Chip Rate (LCR). Cdma2000 covers IS-2000, IS-95 and IS-856 standards. A TDMA system may implement a radio technology such as Global System for Mobile Communications (GSM). An OFDMA system may implement a radio technology such as Evolved UTRA (E-UTRA), IEEE 802.11, IEEE 802.16, IEEE 802.20, Flash-OFDM®, etc. UTRA, E-UTRA, and GSM are part of Universal Mobile Telecommunication System (UMTS). Long Term Evolution (LTE) is an upcoming release of UMTS that uses E-UTRA. UTRA, E-UTRA, GSM, UMTS and LTE are described in documents from an organization named “3rd Generation Partnership Project” (3GPP). Cdma2000 is described in documents from an organization named “3rd Generation Partnership Project 2” (3GPP2). These various radio technologies and standards are known in the art.

Additionally, single carrier frequency division multiple access (SC-FDMA), which utilizes single carrier modulation and frequency domain equalization is another wireless communication technique. A SC-FDMA system can have similar performance and the same overall complexity as those of an OFDMA system. SC-FDMA signal has lower peak-to-average power ratio (PAPR) because of its inherent single carrier structure. SC-FDMA has drawn great attention, especially in uplink communications where lower PAPR greatly benefits the mobile terminal in terms of transmit power efficiency. Using SC-FDMA technique is currently a working assumption for uplink multiple access scheme in 3GPP Long Term Evolution (LTE), or Evolved UTRA. All of the above wireless communication techniques and standards may be used with the data centric multiplexing algorithms described herein.

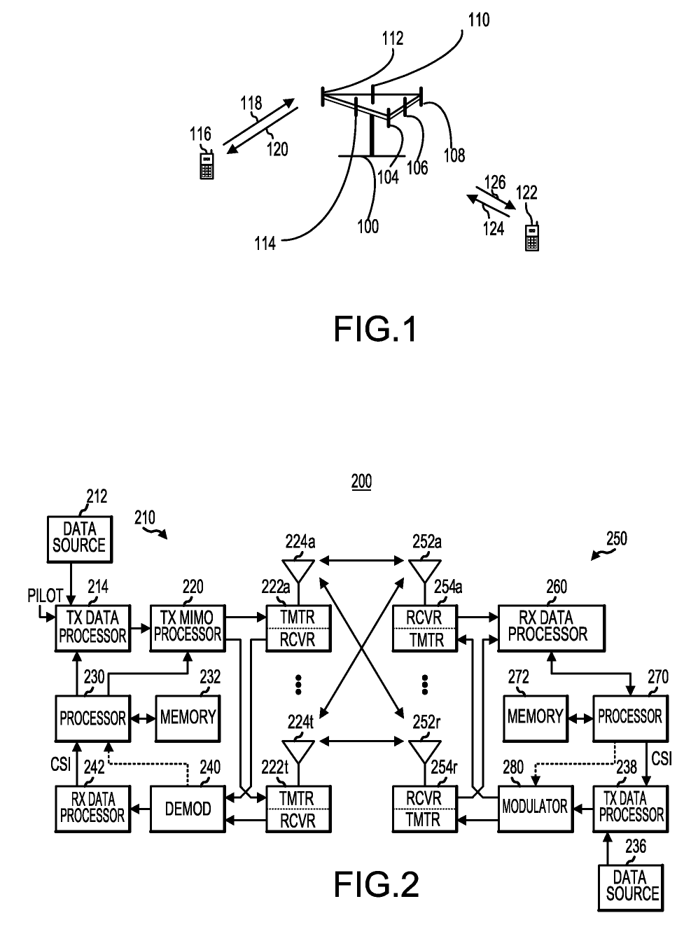

FIG. 1 is a block diagram illustrating an example of a multiple access wireless communication system. As illustrated in FIG. 1, an access point 100 (AP) includes multiple antenna groups, one including 104 and 106, another including 108 and 110, and an additional including 112 and 114. In FIG. 1, only two antennas are shown for each antenna group, however, more or fewer antennas may be utilized for each antenna group. Access terminal 116 (AT) is in communication with antennas 112 and 114, where antennas 112 and 114 transmit information to access terminal 116 over forward link 120 and receive information from access terminal 116 over reverse link 118. Access terminal 122 is in communication with antennas 106 and 108, where antennas 106 and 108 transmit information to access terminal 122 over forward link 126 and receive information from access terminal 122 over reverse link 124. In a FDD system, communication links 118, 120, 124 and 126 may use different frequency for communication. For example, forward link 120 may use a different frequency then that used by reverse link 118. Each group of antennas and/or the area in which they are designed to communicate is often referred to as a sector of the access point. In one example, antenna groups each are designed to communicate to access terminals in a sector, of the areas covered by access point 100.

In communication over forward links 120 and 126, the transmitting antennas of access point 100 utilize beamforming in order to improve the signal-to-noise ratio of forward links for the different access terminals 116 and 124. Also, an access point using beamforming to transmit to access terminals scattered randomly through its coverage causes less interference to access terminals in neighboring cells than an access point transmitting through a single antenna to all its access terminals. An access point may be a fixed station. An access point may also be referred to as an access node, a base station or some other similar terminology known in the art. An access terminal may also be called a mobile station, a user equipment (UE), a wireless communication device or some other similar terminology known in the art.

FIG. 2 is a block diagram illustrating an example of a wireless MIMO communication system. FIG. 2 shows a transmitter system 210 (also known as an access point) and a receiver system 250 (also known as an access terminal) in a MIMO system 200. At the transmitter system 210, traffic data for a number of data streams is provided from a data source 212 to a transmit (TX) data processor 214. In one example, each data stream is transmitted over a respective transmit antenna. TX data processor 214 formats, codes, and interleaves the traffic data for each data stream based on a particular coding scheme selected for that data stream to provide coded data.

The coded data for each data stream may be multiplexed with pilot data using OFDM techniques. The pilot data is typically a known data pattern that is processed in a known manner and may be used at the receiver system to estimate the channel response. The multiplexed pilot and coded data for each data stream is then modulated (i.e., symbol mapped) based on a particular modulation scheme (e.g., BPSK, QSPK, M-PSK, or M-QAM) selected for that data stream to provide modulation symbols. The data rate, coding, and modulation for each data stream may be determined by instructions performed by processor 230.

The modulation symbols for all data streams are then provided to a TX MIMO processor 220, which may further process the modulation symbols (e.g., for OFDM). TX MIMO processor 220 then provides N_{T} modulation symbol streams to N_{T} transmitters (TMTR) 222a through 222t. In one example, the TX MIMO processor 220 applies beamforming weights to the symbols of the data streams and to the antenna from which the symbol is being transmitted. Each transmitter 222a, or, 222t receives and processes a respective symbol stream to provide one or more analog signals, and further conditions (e.g., amplifies, filters, and upconverts) the analog signals to provide a modulated signal suitable for transmission over the MIMO channel. N_{T} modulated signals from transmitters 222a through 222t are then transmitted from N_{T} antennas 224a through 224t, respectively.

At receiver system 250, the transmitted modulated signals are received by N_{R} antennas 252a through 252r and the received signal from each antenna 252a, or 252r is provided to a respective receiver (RCVR) 254a through 254r. Each receiver 254 a, . . . or 254r conditions (e.g., filters, amplifies, and downconverts) a respective received signal, digitizes the conditioned signal to provide samples, and further processes the samples to provide a corresponding “received” symbol stream.

A RX data processor 260 then receives and processes the N_{R} received symbol streams from N_{R} receivers 254a through 254r based on a particular receiver processing technique to provide N_{T} “detected” symbol streams. The RX data processor 260 then demodulates, deinterleaves, and decodes each detected symbol stream to recover the traffic data for the data stream. The processing by RX data processor 260 is complementary to that performed by TX MIMO processor 220 and TX data processor 214 at transmitter system 210. A processor 270 periodically determines which pre-coding matrix to use (discussed below). Processor 270 formulates a reverse link message comprising a matrix index portion and a rank value portion.

The reverse link message may comprise various types of information regarding the communication link and/or the received data stream. The reverse link message is then processed by a TX data processor 238, which also receives traffic data for a number of data streams from a data source 236, modulated by a modulator 280, conditioned by transmitters 254a through 254r, and transmitted back to transmitter system 210.

At transmitter system 210, the modulated signals from receiver system 250 are received by antennas 224a through 224t, conditioned by receivers 222a through 222t, demodulated by a demodulator 240, and processed by a RX data processor 242 to extract the reserve link message transmitted by the receiver system 250. Processor 230 then determines which pre-coding matrix to use for determining the beamforming weights, then the processor 230 processes the extracted message. One skilled in the art would understand that the transceivers 222a through 222t are called transmitters in the forward link and receivers in the reverse link. Similarly, one skilled in the art would understand that the transceivers 254a through 254r are called receivers in the forward link and transmitters in the reverse link.

As stated above, depending on the channel error characteristics and throughput versus latency requirements on the system, error detection or error correction might be preferred. Hybrid ARQ (HARQ) is a third error control category which combines features of both error detection and error correction in an attempt to attain the benefits of both techniques. In one example of HARQ, the first transmission of a transmit data frame may contain only error detection bits. If the receiver determines that the data frame is received without error, no retransmission is requested. However, if the receiver determines that the data frame is received in error, using the error detection bits, then an error detection message is sent back to the transmitter, which sends a second transmission of the transmit data frame along with additional error correction bits. Then, if the receiver determines that the data frame is again received in error, beyond the capability of the additional error correction bits, another error detection message is sent back to the transmitter, which sends a third transmission of the transmit data frame along with a separate set of error correction bits. In general, HARQ retransmissions may be repeated for the same transmit data frame until it is received without error or up to a predetermined maximum number of retransmissions, whichever occurs first.

In one example, in a Ultra Mobile Broadband (UMB) system for the Forward Link Data Channel (FLDCH), the incoming Media Access Control (MAC) packets are first split into subpackets, whose length is less than or equal to, for example, 4 kbits. Then the subpackets are fed into a turbo/convolutional encoder to be encoded, interleaved and repeated. The output bit stream for each subpacket, called the codeword, could be, for example, 5 times longer than the subpacket, due to the forward error correction overhead. The codeword is then transmitted across multiple HARQ transmissions with repetition if necessary. The HARQ transmissions are in general separated by a length of time. For instance, in HARQ8, the codeword is transmitted once every 8 frames. For each transmitted frame, only partial bits of the entire codeword are transmitted. In the conventional design, the entire encoded codeword is stored in memory. The total memory required will be at least 5 times the sum of length of all incoming MAC packets. For example in the forward link of UMB, assuming worst case numbers (i.e. highest packet format for all the tiles (128)) 4 layers and an HARQ interlace depth of 8 frames, the conventional design requires around 25 Mbit on-chip memory.

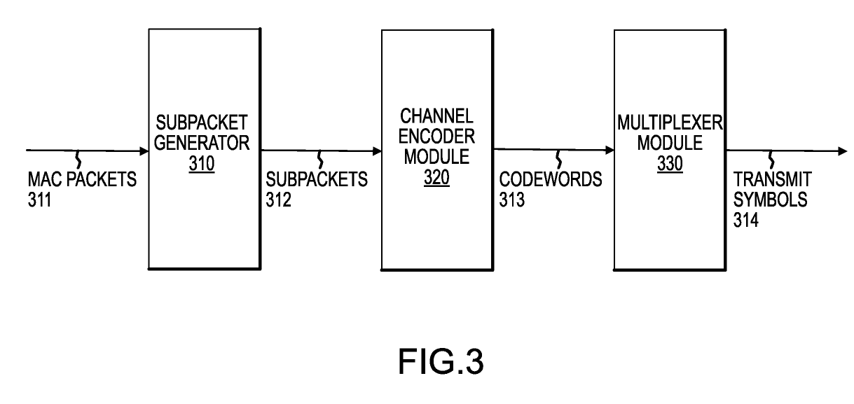

FIG. 3 is a block diagram illustrating an example of a transmit data processor for HARQ encoding. The transmit data processor 300 assembles and encrypts MAC packets 311. Subpacket generator 310 accepts MAC packets 311 at its input and converts them into subpackets 312 that are less than, for example, 4 kbits in length. Channel encoder module 320 accepts the subpackets 312 and produces codewords 313 as outputs. Multiplexer module 330 accepts the codewords 313 as inputs and produces transmit symbols 314 with a particular resource assignment within a particular HARQ transmission. In one aspect, the transmit data processor 300 provides a subpacket interleaving table and maintains a HARQ history along with the multiplexer module 330.

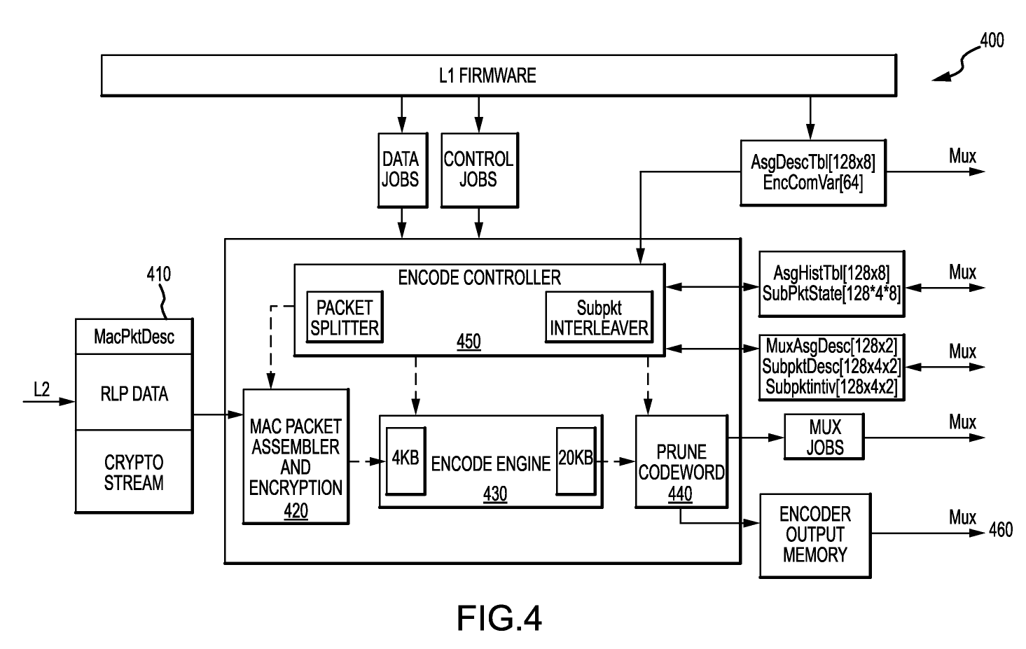

FIG. 4 is a block diagram illustrating an example of the front-end of the transmit data processor 400 of FIG. 3. MAC packets, also known as layer 2 (L2) packets, are accepted by the input L2 module 410, which performs the Radio Link Protocol (RLP) for initial fragmentation. In one aspect, the subpacket generator 310 performs the RLP for initial fragmentation. Next, the MAC packets are sent to the MAC packet assembler and encryptor 420 for assembly and encryption. The encode engine 430 implements the channel encoding under the control of the encode controller 450. The pruner 440 prunes codewords to reduce the channel encoding overhead. Finally, the pruned codewords are sent to the encoder output memory 450 for temporary storage prior to transmission to the multiplexer (Mux 460).

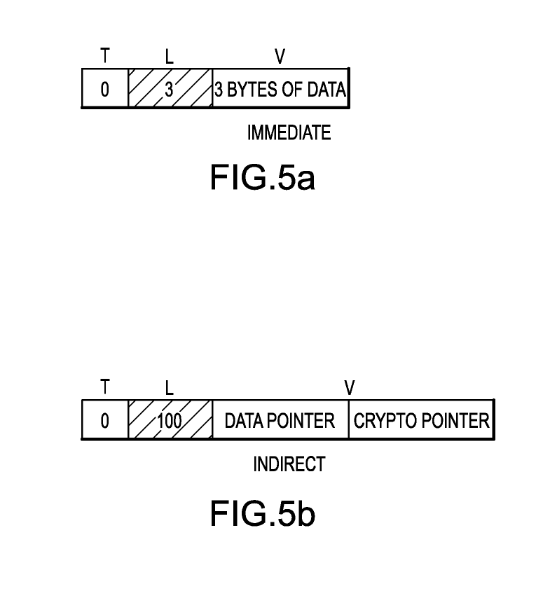

The input L2 module 410 generates the RLP headers, RLP data, and the crypto stream. The information generated by the input L2 module 410 enables the MAC packet assembler and encryptor 420 to assemble the subpacket. The MAC packet descriptor is illustrated in FIGS. 5a and 5b, for immediate and indirect (i.e., pointer) cases, respectively. The MAC packet descriptor is a string of type-length-value (TLV) parameters for two cases, immediate and pointer (i.e., indirect). An assignment descriptor provides a pointer to where the MAC packet descriptor is stored in memory (e.g. for each layer in the case of multi-codeword multiple input-multiple output (MCWMIMO)). The MAC packet is assembled one subpacket at a time.

In one example, the transmit data processor of FIG. 4 receives information from firmware. At a frame boundary, the firmware downloads hopping tables and the pilot scramble sequence. The firmware also sends commands to set frame variables for the EncAsgDesc state variable already in memory and sends commands to encode/multiplex known channels. Next, when assignments are received from the MAC layer, the firmware downloads the EncAsgDesc state variable and changes it if necessary (e.g. the tile assignment is changed, power scale is changed, etc.), and sends commands to encode/multiplex channels. Next, when de-assignments are received from the MAC layer, the firmware sends commands to reset the EncAsgDesc state variable Finally, when the Return Link Acknowledgement (RLACK) message is received, the firmware sends commands to reset EncAsgDesc and changes it if necessary (e.g., when one or more layers of multi-codeword multiple input-multiple output (MCWMIMO) are acknowledged).

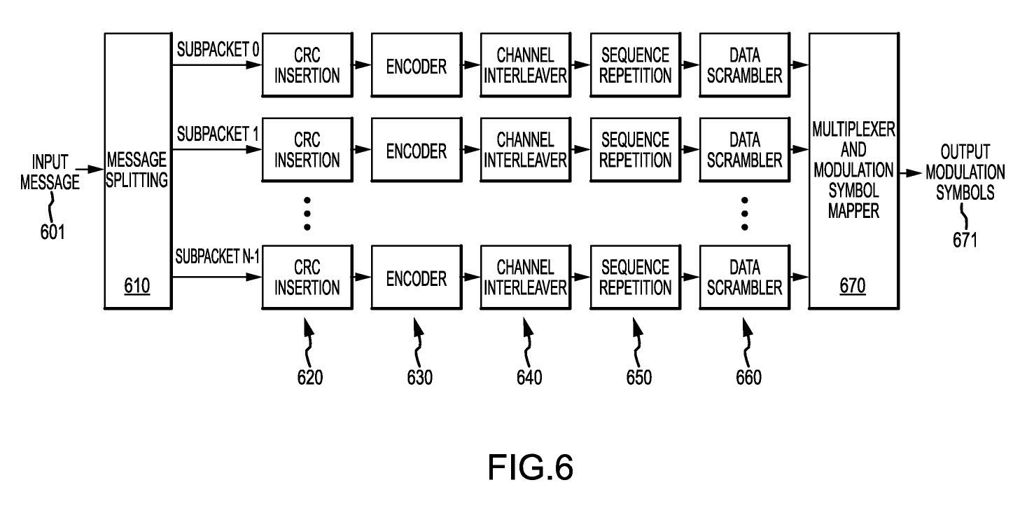

FIG. 6 is a block diagram illustrating a more detailed example of a transmit data processor for HARQ encoding. An input message 601 is received and split into a plurality of subpackets by a message splitter 610. In one aspect, subpacket lengths are limited to no greater than 4096 bits each. Each subpacket is then sent to a cyclic redundancy check (CRC) insertion module 620 where error detection bits are produced and appended to each subpacket. In one aspect, the error detection bits are computed as a 24 bit CRC code. Next, encoder 630 produces encoded subpackets for error correction. In one aspect, the encoder 630 is a turbo encoder. In another aspect, the encoder 630 is a convolutional encoder. Next, channel interleaver 640 interleaves (i.e., shuffles) the encoded subpackets to provide resiliency against burst errors. The sequence repetition module 650 and data scrambler 660 perform additional signal processing on the interleaved encoded subpackets. In one aspect, a data scrambling seed is passed through the EncJob data interface. Finally, multiplexer and modulation symbol mapper 670 combines the scrambled subpackets and supplies output modulation symbols 671.

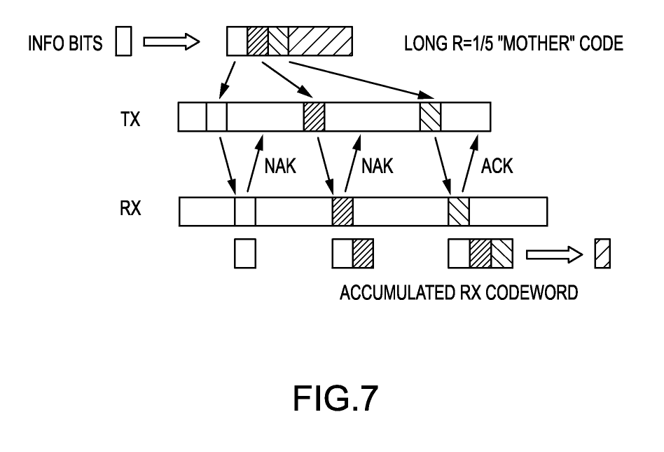

FIG. 7 illustrates an example of a hybrid ARQ operation. In one example, the codeword is comprised of a long mother code with code rate R=⅕. In one aspect, the transmitter incrementally sends parity bits for error detection and/or error correction in each transmission. In one example for UMB, up to six transmissions may be sent. Repetition is used when the number of transmitted bits exceeds the mother codeword block length. In one aspect, the channel encoder module 320 does not store the entire mother code across transmissions. Instead the channel encoder module 320 saves the channel encoder module 320 input across transmissions and runs the channel encoder module 320 for each transmission by maintaining the history state across transmissions.

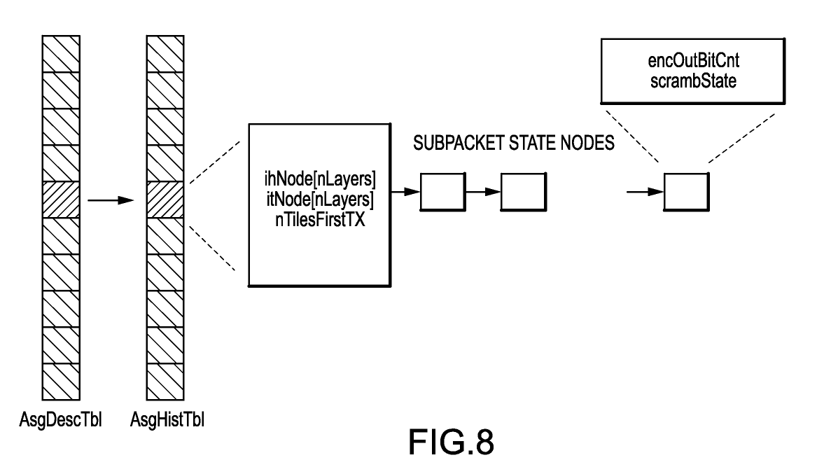

FIG. 8 illustrates an example of an assignment history mechanization. As shown, an assignment description table, AsgDescTbl, feeds an assignment history table, AsgHistTbl. Each cell of the two tables is comprised of three state variables: ihNode[nLayers], itNode[nLayers], and nTilesFirst Tx. State nodes are initialized by the channel encoder module 320 and updated by the multiplexer after each HARQ transmission. The state variable nTilesFirstTx is used to maintain the same MAC packet size even if the number of tiles changes after the first transmission. In one aspect, a tile is an N×M rectangle which is defined on a frequency-time domain, where N is the number of tones and M is the number of symbols. An additional state variable, encOutCnt, is a running counter of the number of bits multiplexed out which is maintained from one transmission to the next for each subpacket (which, for example, is not required for UMB but may be required by another system).

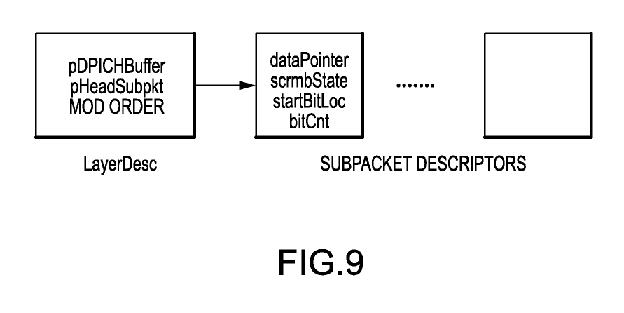

FIG. 9 illustrates an example multiplexer assignment description, showing the relationship between LayerDesc and Subpacket Descriptors. LayerDesc includes the state variables pDPICHBuffer, pHeadSubpkt, Mod order. The Subpacket Descriptors include the state variables dataPointer, scrmbState, startBitLoc, and bitCnt. For each encode command, the channel encoder module 320 sets up a MuxAsgDesc state variable and issues a corresponding muxJob with the following state variables: pointer to the EncAsgDesc; layer descriptor for each layer; table addresses-hop, subpacket interleaver, etc.; and extended flag. The subpacket descriptor has all the information needed by the multiplexer to process the subpacket. At the beginning of each transmission, the channel encoder module 320 copies some variables from the subpacket state nodes and encJob label into the subpacket descriptors. The multiplexer keeps updating the subpacket descriptor and upon termination of multiplexer job, copies these variables over to the state nodes.

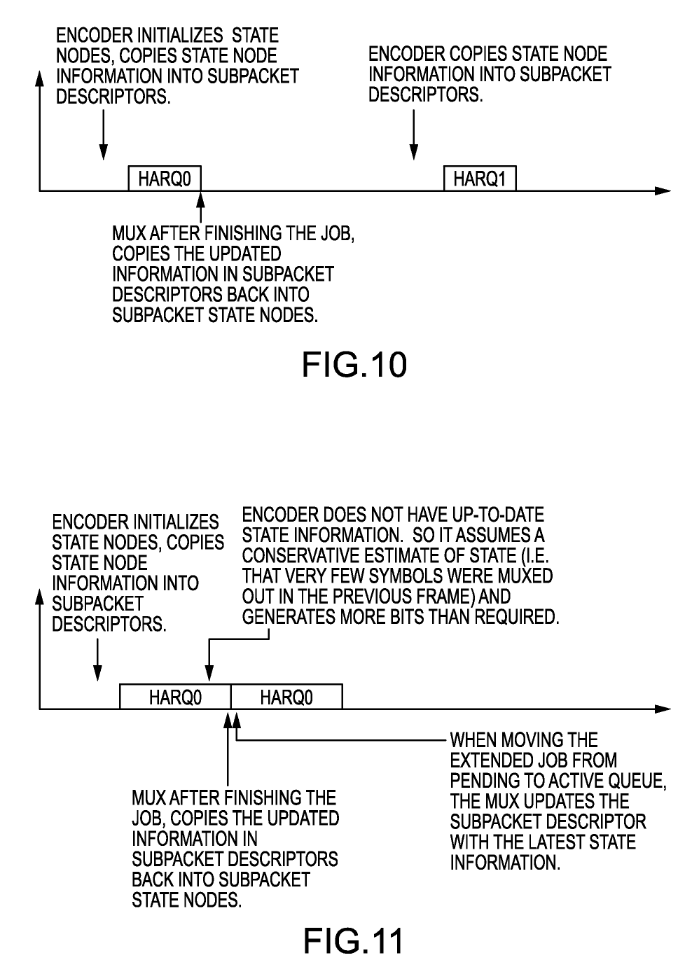

FIG. 10 illustrates an example timeline for the HARQ transmissions. The channel encoder module 320 initializes the state nodes and copies state node information into subpacket descriptors prior to the first HARQ0 transmission. Subsequently, the multiplexer multiplexes the subpacket and copies the updated information in subpacket descriptors back into subpacket state nodes. Then, the channel encoder module 320 copies state node information into subpacket descriptors prior to the second HARQ1 transmission.

FIG. 11 illustrates an example timeline for HARQ transmissions with extended frames, i.e., with consecutive HARQ transmissions. The channel encoder module 320 initializes the state nodes and copies state node information into subpacket descriptors prior to the first HARQ0 transmission. In this case, the channel encoder module 320 does not have up-to-date state information during the first HARQ0 transmission, so it assumes a conservative estimate of state, i.e., that very few symbols were multiplexed out in the previous frame, and generates more bits than required. Subsequently, the multiplexer multiplexes the subpacket and copies the updated information in subpacket descriptors back into subpacket state nodes. During the second HARQ0 transmission, the multiplexer updates the subpacket descriptor with the latest state information when moving the extended job from pending and active queues.

In one aspect, the required on-chip memory is drastically reduces to, for example, less than 1 Mbit. Referring back to FIG. 3, in one example, the entire codeword 313 is not stored at once. Instead, for each HARQ transmission, the channel encoder module 320 will run again to regenerate the entire codeword and save the bits required for this frame transmission. The memory saving is then five times the conventional design. Although channel encoder module 320 reruns for all HARQ transmissions, it does not increase the channel encoder peak processor speed budget (measured in million instructions per second, MIPS). This approach is flexible enough to handle any number of HARQ transmissions. The output of the channel encoder module 320 is used by the multiplexer module 330 to paint, i.e. allocate, the data channel (DCH) resources. The channel encoder module 320 always provides enough bits for each subpacket 312. However in the case when a portion of the DCH resource is occupied by some other channels, the multiplexer module 330 might not use all the bits provided for a subpacket 312. To handle such cases, a set of state variables is maintained for each subpacket, initialized by the channel encoder module 320 at the start of the first HARQ transmission and then updated by the multiplexer module 330 at the end of each transmission. While encoding the data for each transmission, the channel encoder module 320 uses these state variables to locate the part of the codeword 313 to be written to memory for each subpacket 312.

The maintenance of state variables by the channel encoder module 320 and/or by the multiplexer module 330 simplifies the design of the channel encoder module 320 because it does not require knowledge of any other channels which overlap with the DCH resource (e.g. channel quality indicator (CQI), beacon, etc). The channel encoder module 320 is always working on assignments scheduled for the next frame, while the multiplexer module 330 is working on the current frame. In the case when an assignment spreads across contiguous frames (extended or elongated frames) the channel encoder module 320 will not have up-to-date state variable information from the multiplexer module 330. In this case, the channel encoder module 320 just assumes some worst case values for the state variables and provides some extra bits for each subpacket 312. By the time the multiplexer module 330 gets to the next frame, the state variables will be updated and used to select only the appropriate bits.

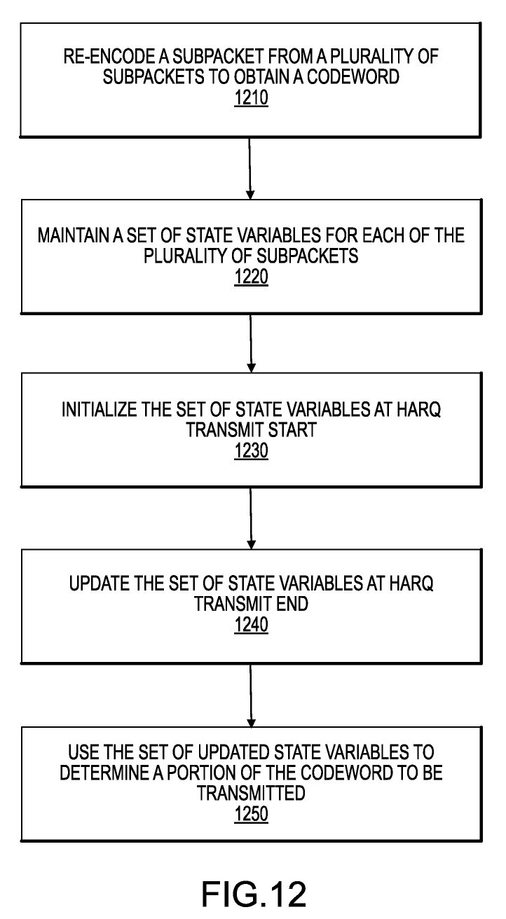

FIG. 12 illustrates an example flow diagram for hybrid automatic repeat request (HARQ) encoding with low memory requirement. In block 1210, re-encode a subpacket from a plurality of subpackets to obtain a codeword. Following block 1210, in block 1220, maintain a set of state variables for each of the plurality of subpackets, and in block 1230, initialize the set of state variables at HARQ transmit start. Transmit start means beginning of a HARQ transmission. Following block 1230, in block 1240, update the set of state variables at HARQ transmit end. Transmit end means end of a HARQ transmission. And, in block 1250, use the set of updated state variables to determine a portion of the codeword to be transmitted.

One skilled in the art would understand that the steps disclosed in the example flow diagram in FIG. 12 can be interchanged in their order without departing from the scope and spirit of the present disclosure. Also, one skilled in the art would understand that the steps illustrated in the flow diagram are not exclusive and other steps may be included or one or more of the steps in the example flow diagram may be deleted without affecting the scope and spirit of the present disclosure.

Those of skill would further appreciate that the various illustrative components, logical blocks, modules, circuits, and/or algorithm steps described in connection with the examples disclosed herein may be implemented as electronic hardware, firmware, computer software, or combinations thereof. To clearly illustrate this interchangeability of hardware, firmware and software, various illustrative components, blocks, modules, circuits, and/or algorithm steps have been described above generally in terms of their functionality. Whether such functionality is implemented as hardware, firmware or software depends upon the particular application and design constraints imposed on the overall system. Skilled artisans may implement the described functionality in varying ways for each particular application, but such implementation decisions should not be interpreted as causing a departure from the scope or spirit of the present disclosure.

For example, for a hardware implementation, the processing units may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, other electronic units designed to perform the functions described therein, or a combination thereof. With software, the implementation may be through modules (e.g., procedures, functions, etc.) that perform the functions described therein. The software codes may be stored in memory units and executed by a processor unit. Additionally, the various illustrative flow diagrams, logical blocks, modules and/or algorithm steps described herein may also be coded as computer-readable instructions carried on any computer-readable medium known in the art or implemented in any computer program product known in the art.

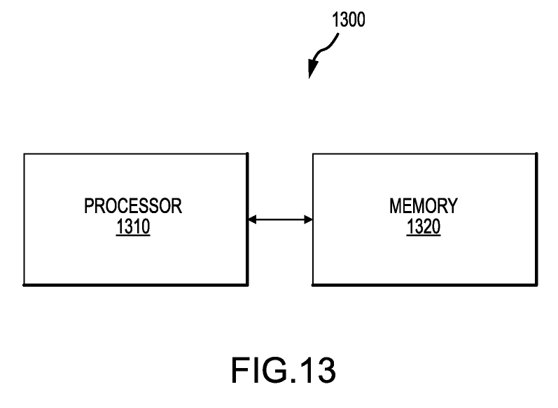

In one example, the illustrative components, flow diagrams, logical blocks, modules and/or algorithm steps described herein are implemented or performed with one or more processors. In one aspect, a processor is coupled with a memory which stores data, metadata, program instructions, etc. to be executed by the processor for implementing or performing the various flow diagrams, logical blocks and/or modules described herein. FIG. 13 illustrates an example of a device 1300 comprising a processor 1310 in communication with a memory 1320 for hybrid automatic repeat request (HARQ) encoding with low memory requirement. In one example, the device 1300 is used to implement the algorithm illustrated in either FIG. 12. In one aspect, the memory 1320 is located within the processor 1310. In another aspect, the memory 1320 is external to the processor 1310. In one aspect, the processor includes circuitry for implementing or performing the various flow diagrams, logical blocks and/or modules described herein.

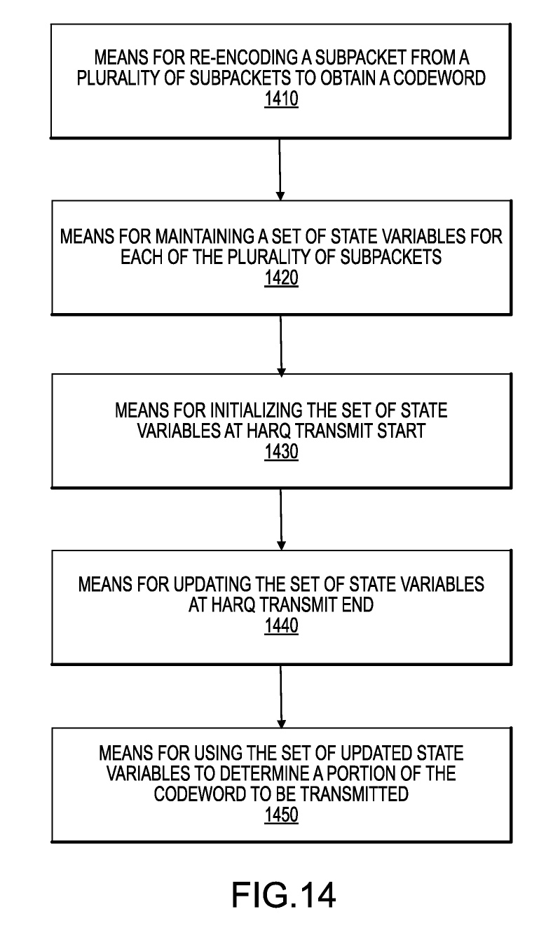

FIG. 14 illustrates an example of a device 1400 suitable for hybrid automatic repeat request (HARQ) encoding with low memory requirement. In one aspect, the device 1400 is implemented by at least one processor comprising one or more modules configured to provide different aspects of for data centric multiplexing as described herein in blocks 1410, 1420, 1430, 1440 and 1450. For example, each module comprises hardware, firmware, software, or any combination thereof. In one aspect, the device 1400 is also implemented by at least one memory in communication with the at least one processor.

The previous description of the disclosed aspects is provided to enable any person skilled in the art to make or use the present disclosure. Various modifications to these aspects will be readily apparent to those skilled in the art, and the generic principles defined herein may be applied to other aspects without departing from the spirit or scope of the disclosure.

1. A method for hybrid automatic repeat request (HARQ) encoding comprising:
re-encoding a subpacket from a plurality of subpackets to obtain a codeword;
maintaining a set of state variables for each of the plurality of subpackets;
initializing the set of state variables at HARQ transmit start;
updating the set of state variables at HARQ transmit end; and
using the set of updated state variables to determine a portion of the codeword to be transmitted.

2. The method of claim 1 further comprising performing a radio link protocol (RLP) on a MAC packet for initial fragmentation to generate the subpacket.

3. The method of claim 2 further comprising packet assembling and encrypting the MAC packet.

4. The method of claim 3 further comprising pruning the codeword to reduce channel encoding overhead.

5. The method of claim 2 wherein the MAC packet is associated with a MAC packet descriptor.

6. The method of claim 5 wherein the MAC packet descriptor is a string of type-length-value (TLV) parameters for an immediate case and an indirect case.

7. The method of claim 1 wherein instructions for performing the steps of claim 1 are received from firmware.

8. The method of claim 1 further comprising:
appending a cyclic redundancy check (CRC) code to the subpacket to produce error detection bits;
encoding the subpacket for error correction; and
interleaving the encoded subpacket with other encoded subpackets to provide resiliency against burst errors.

9. The method of claim 1 wherein the set of state variables comprises at least one of: ihNode[nLayers], itNode[nLayers], nTilesFirst Tx, encOutCnt; pDPICHBuffer, pHeadSubpkt, Mod order, dataPointer, scrmbState, startBitLoc, bitCnt, pointer to the EncAsgDesc; layer descriptor for each layer; table addresses-hop, subpacket interleaver, and extended flag.

10. The method of claim 1 wherein the updating step assumes a conservative state estimate.

11. A transmit data processor for hybrid automatic repeat request (HARQ) encoding comprising:
a channel encoder module configured to:
a) re-encode a subpacket from a plurality of subpackets to obtain a codeword;
b) maintain a set of state variables for each of the plurality of subpackets;
c) initialize the set of state variables at HARQ transmit start; and
d) update the set of state variables at HARQ transmit end; and
a multiplexer module configured to use the set of updated state variables to determine a portion of the codeword to be transmitted.

12. The transmit data processor of claim 11 further comprising a subpacket generator configured to perform a radio link protocol (RLP) on a MAC packet for initial fragmentation to generate the subpacket.

13. The transmit data processor of claim 12 wherein the subpacket generator is further configured to packet assemble and encrypt the MAC packet.

14. The transmit data processor of claim 13 further comprising a pruner configured to prune the codeword to reduce channel encoding overhead.

15. The transmit data processor of claim 12 wherein the MAC packet is associated with a MAC packet descriptor.

16. The transmit data processor of claim 15 wherein the MAC packet descriptor is a string of type-length-value (TLV) parameters for an immediate case and an indirect case.

17. The transmit data processor of claim 11 further comprising:
a cyclic redundancy check (CRC) insertion module for appending a cyclic redundancy check (CRC) code to the subpacket to produce error detection bits;
an encoder for encoding the subpacket for error correction; and
an interleaver for interleaving the encoded subpacket with other encoded subpackets to provide resiliency against burst errors.

18. The transmit data processor of claim 17 wherein the encoder is one of a turbo encoder or a convolutional encoder.

19. The transmit data processor of claim 11 wherein the set of state variables comprises at least one of: ihNode[nLayers], itNode[nLayers], nTilesFirst Tx, encOutCnt; pDPICHBuffer, pHeadSubpkt, Mod order, dataPointer, scrmbState, startBitLoc, bitCnt, pointer to the EncAsgDesc; layer descriptor for each layer; table addresses-hop, subpacket interleaver, and extended flag.

20. The transmit data processor of claim 11 wherein the channel encoder module in updating the set of state variables assumes a conservative state estimate.

21. An apparatus for hybrid automatic repeat request (HARQ) encoding comprising:
means for re-encoding a subpacket from a plurality of subpackets to obtain a codeword;
means for maintaining a set of state variables for each of the plurality of subpackets;
means for initializing the set of state variables at HARQ transmit start;
means for updating the set of state variables at HARQ transmit end; and
means for using the set of updated state variables to determine a portion of the codeword to be transmitted.

22. The apparatus of claim 21 further comprising means for performing a radio link protocol (RLP) on a MAC packet for initial fragmentation to generate the subpacket.

23. The apparatus of claim 22 further comprising means for packet assembling and encrypting the MAC packet.

24. The apparatus of claim 23 further comprising means for pruning the codeword to reduce channel encoding overhead.

25. The apparatus of claim 22 wherein the MAC packet is associated with a MAC packet descriptor.

26. The apparatus of claim 25 wherein the MAC packet descriptor is a string of type-length-value (TLV) parameters for an immediate case and an indirect case.

27. The apparatus of claim 21 further comprising:
means for appending a cyclic redundancy check (CRC) code to the subpacket to produce error detection bits;
means for encoding the subpacket for error correction; and
means for interleaving the encoded subpacket with other encoded subpackets to provide resiliency against burst errors.

28. The apparatus of claim 21 wherein the set of state variables comprises at least one of: ihNode[nLayers], itNode[nLayers], nTilesFirst Tx, encOutCnt; pDPICHBuffer, pHeadSubpkt, Mod order, dataPointer, scrmbState, startBitLoc, bitCnt, pointer to the EncAsgDesc; layer descriptor for each layer; table addresses-hop, subpacket interleaver, and extended flag.

29. A computer-readable medium including program code stored thereon, comprising:
program code for re-encoding a subpacket from a plurality of subpackets to obtain a codeword;
program code for maintaining a set of state variables for each of the plurality of subpackets;
program code for initializing the set of state variables at HARQ transmit start;
program code for updating the set of state variables at HARQ transmit end; and
program code for using the set of updated state variables to determine a portion of the codeword to be transmitted.

30. The computer-readable medium of claim 29 further comprising program code for performing a radio link protocol (RLP) on a MAC packet for initial fragmentation to generate the subpacket.

31. The computer-readable medium of claim 30 further comprising program code for packet assembling and encrypting the MAC packet.

32. The computer-readable medium of claim 31 further comprising program code for pruning the codeword to reduce channel encoding overhead.

33. The computer-readable medium of claim 30 wherein the MAC packet is associated with a MAC packet descriptor.

34. The computer-readable medium of claim 33 wherein the MAC packet descriptor is a string of type-length-value (TLV) parameters for an immediate case and an indirect case.

35. The computer-readable medium of claim 29 further comprising:
program code for appending a cyclic redundancy check (CRC) code to the subpacket to produce error detection bits;
program code for encoding the subpacket for error correction; and
program code for interleaving the encoded subpacket with other encoded subpackets to provide resiliency against burst errors.

36. The computer-readable medium of claim 29 wherein the set of state variables comprises at least one of: ihNode[nLayers], itNode[nLayers], nTilesFirst Tx, encOutCnt; pDPICHBuffer, pHeadSubpkt, Mod order, dataPointer, scrmbState, startBitLoc, bitCnt, pointer to the EncAsgDesc; layer descriptor for each layer; table addresses-hop, subpacket interleaver, and extended flag.
